(19) United States
(12) Patent Application Publication
(10) Pub. No.: US 2024/0105666 A1
(43) Pub. Date: Mar. 28, 2024

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Daisuke Ando, Yokohama Kanagawa (JP); Toyokazu Shibata, Kawasaki Kanagawa (JP)

(21) Appl. No.: 18/177,644

(22) Filed: Mar. 2, 2023

(30) Foreign Application Priority Data
Sep. 22, 2022 (JP) 2022-151662

(51) Int. Cl. H01L 23/00; H01L 23/495

(52) U.S. Cl. CPC H01L 24/37; H01L 23/49555; H01L 24/06; H01L 24/32; H01L 24/40; H01L 24/73; H01L 2224/06181; H01L 2224/32245; H01L 2224/37012; H01L 2224/37147; H01L 2224/40175; H01L 2224/4026; H01L 2224/40475; H01L 2224/73263

(57) ABSTRACT

According to one embodiment, a semiconductor device includes: a semiconductor chip including a first surface, a second surface, a first electrode, a second electrode, and a third electrode; a first conductor including a first portion and a first intermediate portion, a second conductor including a third portion, a second intermediate portion, and a fourth portion, and a length of the first intermediate portion in a second direction being longer than a length of the third portion in the second direction; a third conductor provided on a first surface side of the semiconductor chip; a conductive first connector provided between the first intermediate portion of the first conductor and the third portion of the second conductor; a conductive second connector provided between the second electrode and the first portion; and a conductive third connector provided between the third conductor and the first electrode.

### CROSS-REFERENCE TO RELATED APPLICATION(S)

This application is based upon and claims the benefit of priority from Japanese Patent Application No. 2022-151662, filed Sep. 22, 2022, the entire contents of which are incorporated herein by reference.

### FIELD

Embodiments described herein relate generally to a semiconductor device.

### BACKGROUND

A semiconductor device including a semiconductor chip such as a metal oxide semiconductor field effect transistor (MOSFET) is used for power conversion or the like. For example, when the semiconductor device is a vertical MOSFET, a source electrode and a gate electrode provided on an upper surface of the semiconductor chip are connected to a connector provided above the semiconductor chip.

Examples of related art include JP-A-2021-027146.

### DESCRIPTION OF THE DRAWINGS

FIGS. 1A to 1C are schematic views of a semiconductor device according to an embodiment.

FIG. 2 is a schematic view of the semiconductor device according to the embodiment.

### DETAILED DESCRIPTION

Embodiments provide a semiconductor device with low resistance.

In general, according to one embodiment, the semiconductor device includes: a semiconductor chip including a first surface, a second surface, a first electrode electrically connected to the first surface, a second electrode electrically connected to the second surface, and a third electrode electrically connected to the second surface; a first conductive member including a first portion and a first intermediate portion, the first portion being electrically connected to the second electrode, a direction from the semiconductor chip toward the first portion being along a first direction, a direction from the first portion toward the first intermediate portion being along a second direction intersecting the first direction, the first portion being provided between the semiconductor chip and the first intermediate portion in the first direction; a second conductive member including a third portion, a second intermediate portion, and a fourth portion, a direction from the third portion toward the fourth portion being along the second direction, a length of the first intermediate portion in the second direction being longer than a length of the third portion in the second direction, and the second intermediate portion being provided between the third portion and the fourth portion in the second direction; a third conductive member provided on a first surface side; a conductive first connection member provided between the first intermediate portion and the third portion; a conductive second connection member provided between the second electrode and the first portion; and a conductive third connection member provided between the third conductive member and the first electrode.

Hereinafter, embodiments will be described with reference to the drawings. In the following description, the same members or the like are denoted by the same reference numerals, and description of members or the like once described may be omitted as appropriate.

In the present specification, in order to indicate a positional relationship between components and the like, an upward direction in the drawings is described as “upper”, and a downward direction in the drawings is described as “lower”. In the present specification, concepts of “upper” and “lower” are not necessarily terms indicating a relationship with a direction of gravity.

### Embodiments

A semiconductor device according to an embodiment includes: a semiconductor chip including a first surface, a second surface, a first electrode electrically connected to the first surface, a second electrode electrically connected to the second surface, and a third electrode electrically connected to the second surface; a first conductive member including a first portion and a first intermediate portion, the first portion being electrically connected to the second electrode, a direction from the semiconductor chip toward the first portion being along a first direction, a direction from the first portion toward the first intermediate portion being along a second direction intersecting the first direction, the first portion being provided between the semiconductor chip and the first intermediate portion in the first direction; a second conductive member including a third portion, a second intermediate portion, and a fourth portion, a direction from the third portion toward the fourth portion being along the second direction, a length of the first intermediate portion in the second direction being longer than a length of the third portion in the second direction, and the second intermediate portion being provided between the third portion and the fourth portion in the second direction; a third conductive member including a fifth portion and a sixth portion, the semiconductor chip being provided between the first portion and the fifth portion, a direction from the sixth portion toward the fifth portion being along a third direction intersecting the first direction, the third portion being provided between the fifth portion and the first intermediate portion; a conductive first connection member provided between the first intermediate portion and the third portion; a conductive second connection member provided between the second electrode and the first portion; and a conductive third connection member provided between the fifth portion and the first electrode.

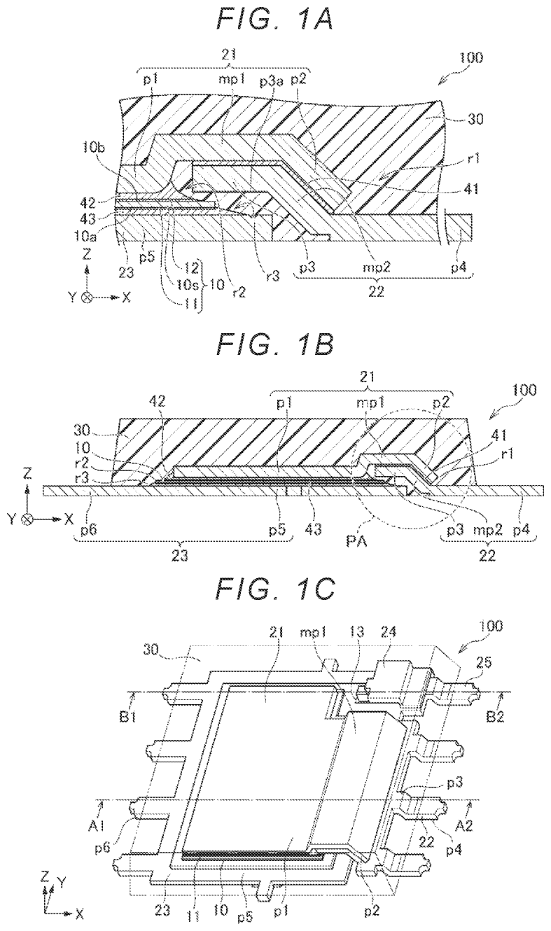

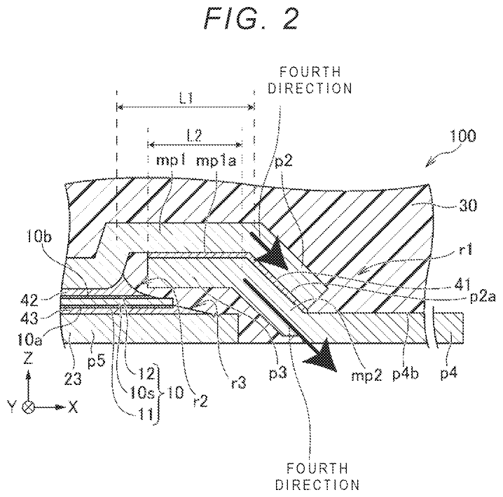

FIGS. 1A to 1C are schematic views of a semiconductor device 100 according to the embodiment. FIG. 1C is a schematic perspective view of the semiconductor device 100 according to the embodiment. FIG. 1B is a schematic cross-sectional view taken along a line A1-A2 in FIG. 1C. FIGS. 1A and 2 are enlarged views of the schematic cross-sectional view taken along the line A1-A2 in FIG. 1C.

The semiconductor device 100 includes a semiconductor chip 10, a first conductive member 21, a second conductive member 22, a third conductive member 23, a fourth conductive member 24, a fifth conductive member 25, a first connection member 41, a second connection member 42, a third connection member 43, and a resin 30.

The semiconductor chip 10 is a chip obtained by providing a vertical MOSFET, an insulated gate bipolar transistor (IGBT), or the like on a semiconductor substrate made of silicon (Si), silicon carbide (SiC), gallium arsenide (GaAs), gallium nitride (GaN), or the like. The semiconductor chip 10 includes a first electrode 11 (for example, a drain electrode), a second electrode 12 (for example, a source electrode), and a semiconductor layer 10s. In this example, the semiconductor layer 10s is provided between the first electrode 11 and the second electrode 12. The semiconductor chip 10 includes a third electrode 13 (for example, a gate electrode). For example, the semiconductor chip 10 includes a first surface (for example, a lower surface) 10a and a second surface (for example, an upper surface) 10b opposed to the first surface 10a. The first electrode 11 is provided on the first surface 10a. The second electrode 12 and the third electrode 13 are provided on the second surface 10b.

As illustrated in FIGS. 1A and 1B, the first conductive member 21 is provided on a second surface 10b side of the semiconductor chip 10, and includes a first portion p1, a first intermediate portion mp1, and a second portion p2. The first conductive member 21 may not include the second portion p2.

The first portion p1 is electrically connected to the semiconductor chip 10. In this example, the first portion p1 is electrically connected to the second electrode 12 (for example, the source electrode) (see FIG. 1A).

Here, an X direction (an X-axis direction), a Y direction (a Y-axis direction) perpendicularly intersecting the X direction, and a Z direction (a Z-axis direction) perpendicularly intersecting the X direction and the Y direction are defined.

A direction from the semiconductor chip 10 toward the first portion p1 is along the first direction (the Z-axis direction). For example, the first portion p1 is positioned above the semiconductor chip 10.

A direction from the first portion p1 toward the first intermediate portion mp1 and the second portion p2 is along the second direction. The second direction intersects the first direction (the Z-axis direction). In this example, the second direction is the X-axis direction. For example, at least a portion of the first conductive member 21 extends along the X-axis direction.

The first intermediate portion mp1 is positioned between the second portion p2 and the first portion p1 in the second direction (the X-axis direction). A position of the first intermediate portion mp1 in the second direction is between a position of the second portion p2 in the second direction and a position of the first portion p1 in the second direction. In this example, the first intermediate portion mp1 is positioned higher than the second portion p2 and the first portion p1. The first portion p1 and the second portion p2 are provided between the semiconductor chip 10 and the first intermediate portion mp1 in the first direction (the Z-axis direction). The first intermediate portion mp1 is provided in order to relax stress applied to the semiconductor chip 10. The first intermediate portion mp1 is, for example, along an X-Y plane and parallel to the X-Y plane.

The second conductive member 22 includes a third portion p3 and a fourth portion p4. A direction from the third portion p3 toward the fourth portion p4 is along the second direction. The second direction intersects the first direction (the Z-axis direction). The third portion p3 is, for example, along the X-Y plane and parallel to the X-Y plane.

The second conductive member 22 may further include a second intermediate portion mp2 in addition to the third portion p3 and the fourth portion p4. In the second direction, the second intermediate portion mp2 is positioned between the third portion p3 and the fourth portion p4. In this example, the third portion p3 is positioned higher than the fourth portion p4. For example, a position of the second intermediate portion mp2 in the first direction (the Z-axis direction) is between a position of the third portion p3 in the first direction and a position of the fourth portion p4 in the first direction.

The second portion p2 is provided above the second intermediate portion mp2. In the first direction, the second portion p2 overlaps the second intermediate portion mp2. That is, the second portion p2 is provided along the second intermediate portion mp2.

As illustrated in FIG. 2, a length L 1 of the first intermediate portion mp1 in the second direction (the X-axis direction in this example) is longer than a length L 2 of the third portion p3 in the second direction.

As illustrated in FIG. 1A, the first connection member 41 is provided between the first intermediate portion mp1 and the third portion p3. The first connection member 41 connects the first intermediate portion mp1 and the third portion p3. The first connection member 41 is conductive. The first connection member 41 contains, for example, solder.

The first connection member 41 is preferably further provided between the second portion p2 and the second intermediate portion mp2.

As illustrated in FIG. 2, the second portion p2 and the second intermediate portion mp2 are preferably along a fourth direction intersecting the first direction and the second direction. In other words, the second portion p2 and the second intermediate portion mp2 preferably extend in the fourth direction.

In the first direction, the second surface 10b of the semiconductor chip 10 is preferably provided between the third portion p3 and the first surface 10a of the semiconductor chip 10. Further, the second surface 10b of the semiconductor chip 10 is preferably provided between a lower surface p3a of the third portion p3 and the first surface 10a of the semiconductor chip 10.

A part of the third portion p3 is preferably provided between the semiconductor chip 10 and the first intermediate portion mp1. In other words, the third portion p3 preferably extends above the semiconductor chip 10.

The second electrode 12 (for example, the source electrode) of the semiconductor chip 10 is electrically connected to the second conductive member 22 via the first conductive member 21, the first connection member 41, and the second connection member 42. The fourth portion p4 of the second conductive member 22 serves as an external terminal to be connected to the outside.

Thus, the first conductive member 21 electrically connects the semiconductor chip 10 and the second conductive member 22 (the external terminal). The first conductive member 21 is, for example, a connector. The first conductive member 21 is, for example, a metal plate. The third portion p3 of the second conductive member 22 functions as a post.

The resin 30 covers, for example, these members. The resin 30 is, for example, a sealing resin.

As illustrated in FIGS. 1B and 1C, the resin 30 does not cover the fourth portion p4 of the second conductive member 22. The fourth portion p4 is exposed from the resin 30. As a result, the fourth portion p4 can be electrically connected to the outside.

In one hand, as illustrated in FIG. 1B, the resin 30 is provided above the first conductive member 21. For example, the first portion p1 is positioned between a part of the resin 30 and the semiconductor chip 10 in the Z-axis direction.

As illustrated in FIGS. 1A and 1B, the second connection member 42 is positioned between the semiconductor chip 10 and the first portion p1. The second connection member 42 connects the semiconductor chip 10 and the first portion p1. The second connection member 42 is conductive. The second connection member 42 contains, for example, solder. The second connection member 42 electrically connects the second electrode 12 of the semiconductor chip 10 and the first portion p1.

As illustrated in FIG. 1B, the third conductive member 23 is provided on a first surface 10a side of the semiconductor chip 10, and includes a fifth portion p5 and a sixth portion p6. In the first direction (the Z-axis direction), the fifth portion p5 overlaps the semiconductor chip 10. A direction from the fifth portion p5 toward the semiconductor chip 10 is along the first direction (the Z-axis direction). The third portion p3 is provided between the fifth portion p5 and the first intermediate portion mp1. A direction from the sixth portion p6 toward the fifth portion p5 is along a third direction intersecting the first direction. In this example, the third direction is the X direction. The second direction and the third direction may be consistent with each other. The semiconductor chip 10 is provided between the first portion p1 and the fifth portion p5. The third portion p3 is provided between the fifth portion p5 and the first intermediate portion mp1.

The third conductive member 23 is, for example, a bed. The third conductive member 23 may function as a heat dissipation path for heat generated in the semiconductor chip 10. The third conductive member 23 is, for example, a metal member having a plate shape.

At least a part of the sixth portion p6 of the third conductive member 23 is not covered with the resin 30. At least a portion of the sixth portion p6 is exposed from the resin 30. The sixth portion p6 serves as another external terminal to be connected to the outside.

As illustrated in FIG. 1A, the third connection member 43 is provided between the fifth portion p5 and the semiconductor chip 10. In this example, the third connection member 43 is provided between the fifth portion p5 and the first electrode 11 (for example, the drain electrode). The third connection member 43 is conductive. The third connection member 43 contains, for example, solder. The third connection member 43 electrically connects the fifth portion p5 and the first electrode 11 of the semiconductor chip 10.

Thus, the first conductive member 21 is electrically connected to the second electrode 12 (for example, the source electrode). The second conductive member 22 is electrically connected to the second electrode 12 via the first conductive member 21. The third conductive member 23 is electrically connected to the first electrode 11 (for example, the drain electrode).

The fourth conductive member 24 is provided, for example, on the second surface 10b side of the semiconductor chip 10, and is electrically connected to the third electrode 13 (for example, the gate electrode) by a conductive connection member (not illustrated) (see FIG. 1C).

The fifth conductive member 25 is electrically connected to the fourth conductive member 24 by, for example, a conductive connection member (not illustrated).

The third electrode 13 (for example, the gate electrode) of the semiconductor chip 10 is electrically connected to the fifth conductive member 25 via the fourth conductive member 24. The fifth conductive member 25 serves as an external terminal to be connected to the outside.

Thus, the fourth conductive member 24 electrically connects the semiconductor chip 10 and the fifth conductive member 25 (the external terminal). The fourth conductive member 24 is, for example, a connector. The fourth conductive member 24 is, for example, a metal plate. A part of the fifth conductive member 25 functions as a post.

As illustrated in FIG. 1C, a part of the fifth conductive member 25 is not covered with the resin 30. As a result, a part of the fifth conductive member 25 can be electrically connected to the outside.

For example, metal such as copper (Cu) is used for the first conductive member 21, the second conductive member 22, the third conductive member 23, the fourth conductive member 24, and the fifth conductive member 25. The first conductive member 21, the second conductive member 22, the fourth conductive member 24, and the fifth conductive member 25 have, for example, a shape obtained by bending a plate-shaped metal member. Solder or the like is used for the connection members including the first connection member 41, the second connection member 42, and the third connection member 43. The resin 30 is provided with, for example, an epoxy resin. The resin 30 may contain, for example, a filler containing silicon oxide.

The semiconductor device according to the embodiment is, for example, a small outline package (SOP) type semiconductor device.

The semiconductor device according to the embodiment is required to have low resistance, high heat dissipation, and high reliability. In particular, the low resistance directly relates to electrical characteristics of the semiconductor device including a rated current. Therefore, in the semiconductor device according to the embodiment, the low resistance is particularly important.

The inventors made intensive development and examined resistance of members in the semiconductor device according to the embodiment. As a result, it was clear that the resistance of the first conductive member 21 and the resistance of the second conductive member 22 was large in a package portion excluding the semiconductor chip 10. For this reason, it is important to reduce the resistance of the first conductive member 21 and the resistance of the second conductive member 22 in order to reduce the resistance of the semiconductor device according to the embodiment.

Here, in order to reduce the resistance of the first conductive member 21 and the resistance of the second conductive member 22, it is conceivable to increase a film thickness of the first conductive member 21 and a film thickness of the second conductive member 22. This is preferable also from a viewpoint of dissipating the heat generated from the semiconductor chip 10 via the first conductive member 21 and the second conductive member 22. However, there is a problem that the stress applied to the entire semiconductor device 100 including the semiconductor chip 10 becomes large.

In particular, a manufacturing process of the semiconductor device 100 may include the following process. It is a process in which a member serving as the second conductive member 22 and a member serving as the third conductive member 23 are initially provided in an integrated plate-shaped member, and the second conductive member 22 and the third conductive member 23 are formed by cutting the plate-shaped member later. In this case, the film thickness of the second conductive member 22 is equal to the film thickness of the third conductive member 23. Therefore, when the film thickness of the second conductive member 22 is increased, the film thickness of the third conductive member 23 is also increased. Therefore, there is a problem that as the film thickness of the third conductive member 23 is increased, the stress applied to the entire semiconductor device 100 including the semiconductor chip 10 is further increased. The second conductive member 22 and the third conductive member 23 may be individually processed and formed.

Further, when the stress increases, reliability of connection by the first connection member 41, the second connection member 42, and the third connection member 43 may decrease.

Since a height of the semiconductor device in the Z direction is increased, there is a problem that it is difficult to reduce a size of the semiconductor device.

Therefore, in the semiconductor device according to the embodiment, the length L 1 of the first intermediate portion mp1 of the first conductive member 21 in the second direction is longer than the length L 2 of the third portion p3 in the second direction. The conductive first connection member 41 is provided between the first intermediate portion mp1 and the third portion p3.

As a result, electrical resistance between the first intermediate portion mp1 and the third portion p3 can be reduced. Therefore, the resistance of the semiconductor device can be reduced without increasing the film thickness of the first conductive member 21 and the film thickness of the second conductive member 22. Therefore, the resistance of the semiconductor device can be reduced while minimizing the stress applied to the entire semiconductor device 100 including the semiconductor chip 10.

In other words, in the semiconductor device according to the embodiment, the film thickness of the first conductive member 21 and the film thickness of the second conductive member 22 are made to be larger in a pseudo manner by the first intermediate portion mp1 and the third portion p3. This makes it possible to reduce the resistance of the semiconductor device.

The heat generated from the semiconductor chip 10 is more likely to flow through the third portion p3 via the first intermediate portion mp1. Therefore, fatigue fracture of the semiconductor device is less likely to occur.

Due to internal stress in the semiconductor device, a crack may occur in the first connection member 41. However, in the semiconductor device according to the embodiment, the length L 1 of the first intermediate portion mp1 of the first conductive member 21 in the second direction is long. Therefore, a volume of the first connection member 41 can be increased. As a result, even if a crack is formed to some extent, the first intermediate portion mp1 and the third portion p3 can be connected well.

The first conductive member 21 preferably further includes the second portion p2. In the manufacturing process of the semiconductor device, when the first conductive member 21 is disposed above the second conductive member 22, the first conductive member 21 may rotate in the X-Y plane. As a result, a positional relationship of the first conductive member 21 with respect to the semiconductor chip 10 and the second conductive member 22 is shifted in the X-Y plane. However, since the first conductive member 21 includes the second portion p2, even if the first conductive member 21 attempts to rotate in the X-Y plane, the second portion p2 collides with the second intermediate portion mpg. Therefore, the rotation of the first conductive member 21 in the X-Y plane can be prevented. Therefore, the semiconductor device can be manufactured more easily.

If the second portion p2 and the second intermediate portion mp2 are electrically connected well, the resistance of the semiconductor device can be further reduced.

By providing the first connection member 41 between the second portion p2 and the second intermediate portion mp2, the second portion p2 and the second intermediate portion mp2 are electrically connected well. Therefore, the resistance of the semiconductor device can be further reduced.

In a case in which the second portion p2 and the second intermediate portion mp2 extend in the fourth direction, the rotation of the first conductive member 21 in the X-Y plane can be prevented more favorably. The second portion p2 and the second intermediate portion mp2 can be electrically connected more favorably. The fourth direction is, for example, a direction non-parallel to the first direction and the second direction. In this case, a lower surface p2a of the second portion p2 is a surface non-parallel to an orientation of a lower surface mp1a of the first intermediate portion mp1 or an upper surface p4b of the fourth portion p4. In other words, the lower surface p2a of the second portion p2 is inclined with respect to the orientation of the lower surface mp1a of the first intermediate portion mp1 or the upper surface p4b of the fourth portion p4.

In the first direction, the second surface 10b of the semiconductor chip 10 is preferably provided between the third portion p3 and the first surface 10a. Further, in the first direction, the second surface 10b of the semiconductor chip 10 is preferably provided between the lower surface p3a of the third portion p3 and the first surface 10a of the semiconductor chip 10. As a result, a part of the third portion p3 may extend above the semiconductor chip 10. Therefore, a contact area between the first intermediate portion mp1 and the third portion p3 can be further increased. Therefore, the resistance of the semiconductor device can be further reduced.

A part of the third portion p3 is preferably provided between the semiconductor chip 10 and the first intermediate portion mp1. In other words, the third portion p3 preferably extends above the semiconductor chip 10. This is because the resistance of the semiconductor device can be further reduced.

According to the semiconductor device of the embodiment, a semiconductor device with low resistance can be provided.

While certain embodiments and examples have been described, these embodiments and examples have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device, comprising:
a semiconductor chip comprising a first surface, a second surface, a first electrode electrically connected to the first surface, a second electrode electrically connected to the second surface, and a third electrode electrically connected to the second surface;
a first conductor comprising a first portion and a first intermediate portion, the first portion being electrically connected to the second electrode, a direction from the semiconductor chip toward the first portion being along a first direction, a direction from the first portion toward the first intermediate portion being along a second direction intersecting the first direction, the first portion being provided between the semiconductor chip and the first intermediate portion in the first direction;
a second conductor comprising a third portion, a second intermediate portion, and a fourth portion, a direction from the third portion toward the fourth portion being along the second direction, a length of the first intermediate portion in the second direction being longer than a length of the third portion in the second direction, and the second intermediate portion being provided between the third portion and the fourth portion in the second direction;
a third conductor provided on a first surface side of the semiconductor chip;
a conductive first connector provided between the first intermediate portion of the first conductor and the third portion of the second conductor;
a conductive second connector provided between the second electrode of the semiconductor chip and the first portion of the first conductor; and
a conductive third connector provided between the third conductor and the first electrode of the semiconductor chip.

2. The semiconductor device according to claim 1, wherein the first conductor further includes a second portion, the first intermediate portion is provided between the first portion and the second portion in the second direction, and a direction from the first portion toward the second portion is along the second direction.

3. The semiconductor device according to claim 2, wherein the first connector is further provided between the second portion and the second intermediate portion.

4. The semiconductor device according to claim 2, wherein
the second portion extends in a fourth direction intersecting the first direction and the second direction, and
the second intermediate portion extends in the fourth direction.

5. The semiconductor device according to claim 1, wherein the second surface is provided between the third portion and the first surface in the first direction.

6. The semiconductor device according to claim 5, wherein a part of the third portion is provided between the semiconductor chip and the first intermediate portion.
